(19) United States
(12) Patent Application Publication
(10) Pub. No.: US 2021/0173303 A1
(43) Pub. Date: Jun. 10, 2021

(54) METHOD OF MANUFACTURING MOLD, MOLD, IMPRINT METHOD, IMPRINT APPARATUS, AND METHOD OF MANUFACTURING ARTICLE

(71) Applicant: CANON KABUSHIKI KAISHA, Tokyo (JP)

(72) Inventor: Hiroshi Sato, Tochigi (JP)

(21) Appl. No.: 17/114,017

(22) Filed: Dec. 7, 2020

(30) Foreign Application Priority Data
Dec. 10, 2019 (JP) 2019-223000

(51) Int. Cl. G03F 7/00; B29C 33/38

(52) U.S. Cl. CPC G03F 7/0002; B29C 33/3842

(57) ABSTRACT

The present invention provides a method of manufacturing a mold including performing a process of processing a surface of a base member so that a mark region where a mark is to be formed on the surface, which is to be a pattern surface of the mold, will be recessed lower than a pattern region, and performing a process of a second process of arranging, on the mark region which has been recessed, a mark member made of a material which has an optical physical property different from an optical physical property of the mold and a protection layer configured to cover the mark member so that a difference between a height of a surface of the mark and a height of a surface of the pattern will fall within a predetermined range.

### BACKGROUND OF THE INVENTION

### Field of the Invention

The present invention relates to a method of manufacturing a mold, the mold, an imprint method, an imprint apparatus, and a method of manufacturing an article.

### Description of the Related Art

An imprint technique which is a technique that allows a nanoscale micropattern to be transferred has gained attention as a lithography technique for mass production of devices such as semiconductor devices, liquid crystal display elements, magnetic storage devices, and the like. In an imprint apparatus which employs the imprint technique, an imprint material on a substrate (a silicon wafer or a glass substrate) is molded by using a mold on which a micropattern has been formed.

An imprint apparatus cures an imprint material on a substrate in a state in which the imprint material on the substrate and the mold are in contact with each other, and separates the mold from the cured imprint material to form a projection and groove pattern formed by the imprint material on the substrate. In general, an imprint apparatus employs, as an imprint material curing method, a photocuring method in which an imprint material on a substrate is cured by irradiation with light such as ultraviolet light or the like. Hence, a mold is made of a material, for example, quartz, which can transmit light such as ultraviolet light or the like.

In an imprint apparatus, a mold and a substrate need to be accurately aligned when the mold and an imprint material on the substrate are to be brought into contact with each other. For example, as disclosed in Japanese Patent Laid-Open No. 2011-127979, a die-by-die alignment method is employed as a method of aligning the mold and the substrate. The die-by-die alignment method is a method in which the mold and the substrate are aligned by detecting, for each shot region on the substrate, a mark arranged on the shot region and a mark arranged on the mold.

When a mark is to be detected in the die-by-die alignment method, the mark arranged on the mold is filled with the imprint material. Since quartz that forms the mold has optical physical properties (for example, the refractive index and the like) which are substantially equal to those of the imprint material, a contrast necessary for mark detection may not be obtained if the mark is filled with the imprint material. Hence, Japanese Patent Laid-Open Nos. 2013-30522 and 2019-41126 propose a technique for forming a mark with a material (mark member) which has optical physical properties different from those of the imprint material and quartz so that the mark arranged on the mold can be detected even when the mark has been filled with the imprint material.

However, in a case in which a mark is to be formed with a mark member and a protection layer for suppressing the mark member from peeling during an imprint process or mold cleaning is to be further formed on the mark member, a mark portion of the mold may become higher than a pattern surface (a surface on which the pattern has been formed) of the mold. In such a case, the mark portion of the mold can become deformed in the height direction (Z direction) of the mold and cause distortion when the mold and the imprint material on the substrate are brought into contact with each other.

### SUMMARY OF THE INVENTION

The present invention provides a method of manufacturing a mold which is advantageous in the point of detecting a mark in a state in which the mold is contact with an imprint material and in the point of suppressing deformation when the mold is in contact with the imprint material.

According to one aspect of the present invention, there is provided a method of manufacturing a mold that is used to mold an imprint material and includes a pattern surface on which a pattern to be transferred to a substrate and a mark to be used for alignment with respect to the substrate are formed, the method including performing a first process of processing a surface of a base member so that a mark region where the mark is to be formed on the surface of the base member, which is to be the pattern surface of the mold, will be recessed lower than a pattern region where the pattern is to be formed, and performing a second process of arranging, on the mark region which has been recessed lower than the pattern region, a mark member made of a material which has an optical physical property different from an optical physical property of the mold and a protection layer configured to cover the mark member so that a difference between a height of a surface of the mark and a height of a surface of the pattern will fall within a predetermined range.

Further aspects of the present invention will become apparent from the following description of exemplary embodiments with reference to the attached drawings.

### BRIEF DESCRIPTION OF THE DRAWINGS

FIGS. 1A and 1B are schematic views each showing the arrangement of an imprint apparatus.

FIG. 2 is a view for explaining a mold-side mark and a substrate-side mark.

FIGS. 3A to 3C are views for explaining the mold-side mark and the substrate-side mark.

FIGS. 4A to 4D are sectional views each showing the state of a substrate and a mold in an imprint process.

FIGS. 5A to 5C are views for explaining a mark member and the mold-side mark on which a protection layer has been formed.

FIGS. 6A to 6F are views for explaining a method of manufacturing the mold according to this embodiment.

FIGS. 7A to 7H are views for explaining the method of manufacturing the mold according to this embodiment.

FIGS. 8A to 8F are views for explaining a method of manufacturing an article.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

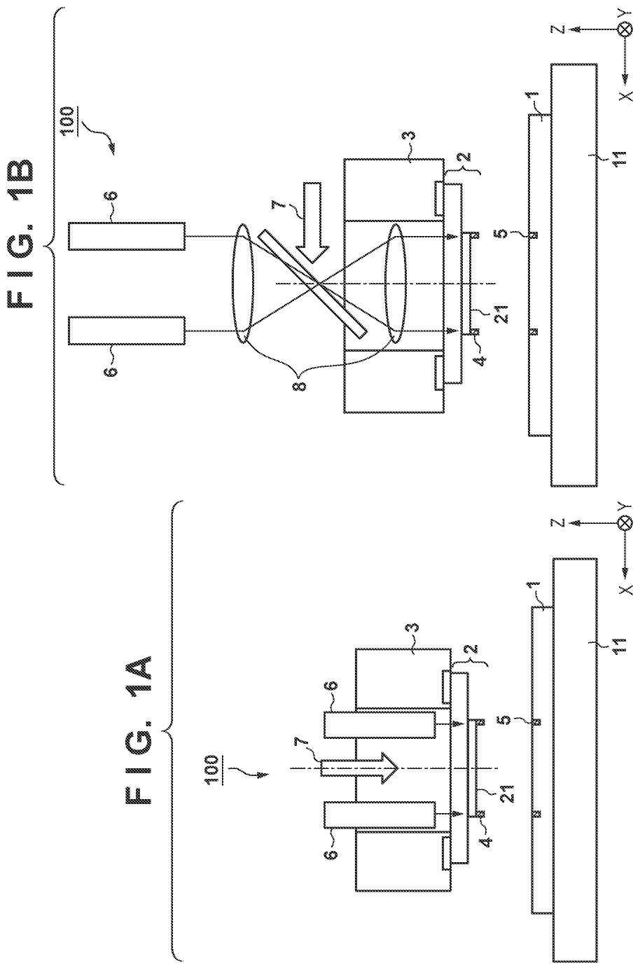

FIGS. 1A and 1B are schematic views showing the arrangement of an imprint apparatus 100. The imprint apparatus 100 is a lithography apparatus that forms a pattern on a substrate and is employed in a lithography process as a manufacturing process of a semiconductor device, a liquid crystal display element, a magnetic storage medium, or the like. The imprint apparatus 100 brings a mold into contact with an uncured imprint material supplied on a substrate and applies curing energy to the imprint material, thereby forming a cured product pattern to which the parent of the mold has been transferred.

As the imprint material, a material (a curable composition) which can be cured by receiving curing energy is used. An electromagnetic wave, heat, or the like is used as the curing energy. As the electromagnetic wave, for example, light selected from the wavelength range of 10 nm (inclusive) to 1 mm (inclusive) is used. More specific examples of the electromagnetic wave are infrared light, a visible light beam, and ultraviolet light.

The curable composition is a composition cured by light irradiation or by heat application. A photo-curable composition cured by light irradiation contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component.

The imprint material may be applied in a film shape onto the substrate by a spin coater or a slit coater. The imprint material may be applied, onto the substrate, in a droplet shape or in an island or film shape formed by connecting a plurality of droplets by using a liquid injection head. The viscosity (the viscosity at 25° C.) of the imprint material is, for example, 1 mPa·s (inclusive) to 100 mPa·s (inclusive).

As the substrate, glass, ceramic, a metal, a semiconductor, a resin, or the like is used. A member made of a material different from that of the substrate may be formed on the surface of the substrate, as needed. More specifically, examples of the substrate are a silicon wafer, a semiconductor compound wafer, and silica glass.

In the specification and the accompanying drawings, directions will be indicated on an XYZ coordinate system in which directions parallel to the surface of a substrate 1 are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that is specified based on coordinates on the X-, Y-, and Z-axes, and a posture is information that is specified by values on the θX-, θY-, and θZ-axes. Positioning means controlling the position and/or the posture. Alignment includes controlling the position and the posture of at least one of the substrate and the mold.

The imprint apparatus 100 employs a photocuring method as an imprint material curing method. The imprint apparatus 100 includes a head 3 which holds a mold 2, a substrate stage 11 which holds the substrate 1, and measuring units 6. The imprint apparatus 100 aiso includes a supplying unit which includes a dispenser for supplying an imprint material onto a substrate, a bridge plate to hold the head 3, a base plate to hold the substrate stage 11, and the like.

The mold 2 is a mold which molds the imprint material on a substrate. The mold 2 has a rectangular outer shape and includes a pattern surface 21 on which a pattern (a projection and groove pattern) to be transferred to (the imprint material on) the substrate 1 has been formed. The mold 2 is made of a material, for example, quartz or the like, which transmits ultraviolet light 7 for curing the imprint material on the substrate. In addition, marks to be used for alignment with respect to the substrate 1, that is, marks (mold-side marks) 4 which are to function as alignment marks have been arranged on the pattern surface 21 of the mold 2.

The head 3 is a holding mechanism that holds the mold 2. The head 3 includes, for example, a mold chuck that vacuum chucks or electrostatically chucks the mold 2 and a mold driving unit that drives (moves) the mold chuck. The mold driving unit drives the mold chuck which has chucked the mold 2, that is, the mold 2 in at least the Z direction. The mold driving unit may also have a function to drive the mold 2 in not only the Z direction, but also the X direction, the Y direction, and the θZ direction.

The substrate 1 is a substrate on which the pattern of the mold 2 is to be transferred. An imprint material is supplied from the supplying unit to the substrate 1. Marks to be used for alignment with respect to the mold 2, that is, marks (substrate-side marks) 5 which function as alignment marks are formed on each of a plurality of shot regions on the substrate 1.

The substrate stage 11 is a holding mechanism that holds the substrate 1. For example, the substrate stage 11 vacuum chucks or electrostatically chucks the substrate 1 via a substrate chuck and is driven by a substrate driving unit. The substrate driving unit drives the substrate stage 11 holding the substrate 11, that is, the substrate 1 in at least the X direction and the Y direction. The substrate driving unit may also have a function to drive the substrate 1 in not only the X direction and the Y direction, but also the Z direction and the θZ direction.

For example, each measuring unit 6 is arranged inside the head 3 as shown in FIG. 1A, and measures the relative position (positional shift) between the corresponding mold-side mark 4 (the mold 2) and the corresponding substrate-side mark 5 (the substrate 1) by optically detecting (observing) the mold-side mark 4 and the substrate-side mark 5. In a case in which it is difficult to arrange the measuring units 6 inside the head 3, the measuring units 6 may detect the respective images of the mold-side marks 4 and the substrate-side marks 5 formed above the head 3 via an imaging optical system 8 as shown in FIG. 1B. In this embodiment, the mold 2 and the substrate 1 are aligned based on the relative position between the mold-side mark 4 and the substrate-side mark 5 which has been measured by each measuring unit 6.

The imprint apparatus 100 emits, from the upper side of the apparatus, the ultraviolet light 7 for curing the imprint material in a state in which the mold 2 and the imprint material on the substrate have been brought into contact with each other. As a result, when the imprint material is cured and subsequently released from the mold 2, a resin layer which is a cured imprint material product on which a pattern structure provided on the parent surface 21 of the mold 2 has been transferred is arranged on the substrate.

In a case in which the imprint apparatus 100 has the arrangement shown in FIG. 1B, a composite prism is arranged on an optical path of the imaging optical system 8 to combine an optical path of each measuring unit 6 and an optical path of an irradiation unit that emits the ultraviolet light 7. In this case, the composite prism suffices to have a characteristic which allows light from the ultraviolet light 7 to be reflected and light (measurement light) from each measuring unit 6 to be transmitted.

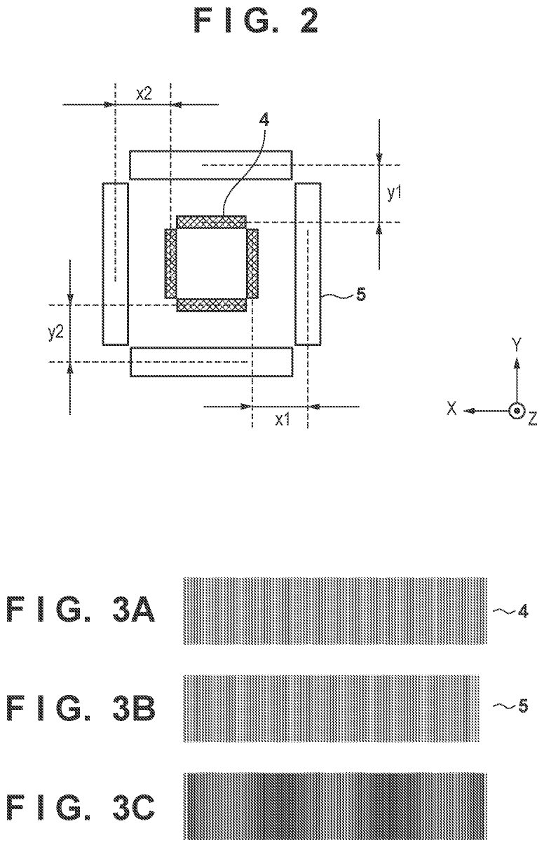

The mold-side marks 4 and the substrate-side marks 5 will be described here. Each mold-side mark 4 and the corresponding substrate-side mark 5 are formed by a mark, for example, a box-in-box mark as shown in FIG. 2, that can be used to obtain their relative position (positional relationship). In FIG. 2, although the black square mark on the inner side is set as the mold-side mark 4 and the hollow square mark on the outer side is set as the substrate-side mark 5, the present invention is not limited to this. It is sufficient as long as one of the black square mark and the hollow square mark is arranged on the substrate 1 and the other is arranged on the mold 2.

When the mold-side mark 4 and the substrate-side mark 5 shown in FIG. 2 are detected, intervals x1, x2, y1, and y2 between the respective sides of the mold-side mark 4 and the substrate-side mark 5 are extracted, and a difference between each of these interval values and a corresponding design value or a difference between the interval x1 and the interval x2 and a difference between the interval y1 and the interval y2 is obtained. As a result, the relative position between the mold-side mark 4 and the substrate-side mark 5 in each of the X direction and the Y direction can be obtained.

In addition, as shown in FIGS. 3A, 3B, and 3C, the relative position between the mold-side mark 4 and the substrate-side mark 5 can be obtained by using moiré. More specifically, a grating pattern as shown in FIG. 3A is set as the mold-side mark 4, and a grating pattern as shown in FIG. 3B is set as the substrate-side mark 5. Since the grating patten shown in FIG. 3A and the grating pattern shown in FIG. 3B are patterns with different grating pitches from each other, moiré (a moiré signal) as shown in FIG. 3C will occur by overlaying the mold-side mark 4 and the substrate-side mark 5. Since the moiré generated by the difference in the grating pitches is an enlargement of the positional shift between the mold-side mark 4 and the substrate-side mark 5, the relative position between the mold-side mark 4 and the substrate-side mark 5 can be measured highly accurately even if the performance (resolution) of each measuring unit 6 is low.

In addition, the relative position between the mold-side mark 4 and the substrate-side mark 5 may be obtained based on the intensity of an optical signal generated in accordance with the relative position between the mold-side mark 4 and the substrate-side mark 5 by making the mold-side mark 4 and the substrate-side mark 5 have equal pitches. For example, the optical signal from the mold-side mark 4 and the substrate-side mark 5 is detected while shifting the relative position of the substrate 1 and the mold 2. The optical signal is strongest when it is detected in a state in which the positions of the mold-side mark 4 and the substrate-side mark 5 match, and the optical signal is weakest when it is detected in a state in which the positions of the mold-side mark 4 and the substrate-side mark 5 are shifted from each other by a half pitch. The relative position of the mold-side mark 4 and the substrate-side mark 5 can be obtained by detecting an optical signal from the mold-side mark 4 and the substrate-side mark 5 based on such a relationship.

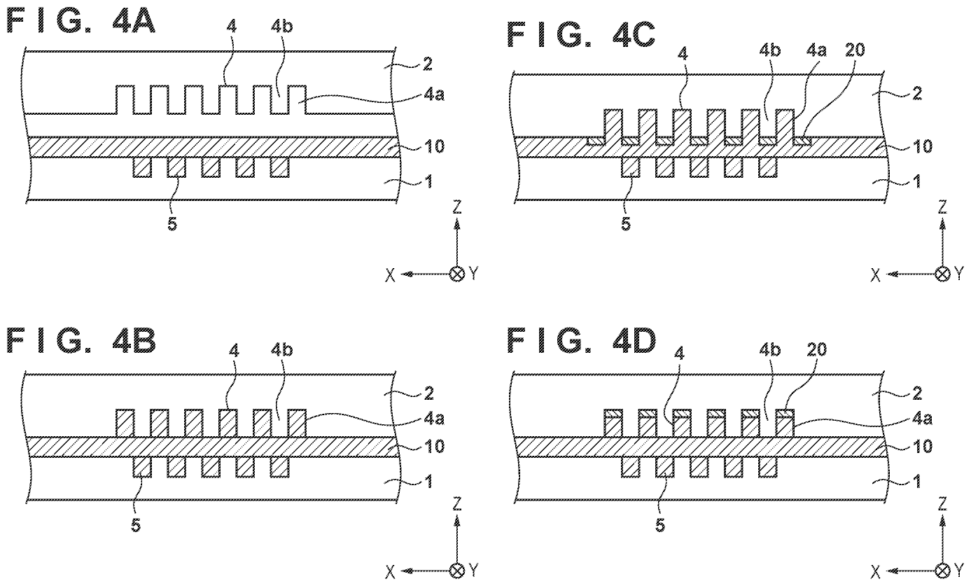

FIGS. 4A, 4B, 4C, and 4D are sectional views schematically showing the state of the substrate 1 (an imprint material 10 on the substrate) and the mold 2 during the imprint process. FIG. 4A shows a (pre-liquid contact) state before the imprint material 10 on the substrate ard the mold 2 are brought into contact with each other. Referring to FIG. 4A, the imprint material 10 has been supplied onto the substrate 1, and the substrate 1 and the mold 2 are facing each other. Note that although the imprint material 10 has been supplied (applied) on the entire surface of the substrate 1 in FIG. 4A, the present invention is not limited to this. For example, droplets of the imprint material 10 can be supplied (dropped) onto the substrate, and the droplets of the imprint material 10 can be pressed and spread out on the substrate by the mold 2 when the mold 2 is brought into contact with the imprint material on the substrate.

FIG. 4B shows a (post-liquid contact) state after the imprint material 10 on the substrate and the mold 2 have been brought into contact. Referring to FIG. 4B, it can be seen that the imprint material 10 on the substrate has filled, based on capillarity, each groove of the mold 2, more specifically, grooves 4a forming the mold-side mark 4.

As described above, since the imprint material 10 needs to be irradiated with the ultraviolet light 7 via the mold 2 when the imprint material 10 on the substrate is to be cured, the mold 2 is made of a material, such as quartz or the like, which can transmit the ultraviolet light 7. If the optical physical properties (for example, the refractive index and the like) of the imprint material 10 and those of the mold 2 are close to each other, the mold-side mark 4 may not be detected or may become difficult to detect, and the measurement of the relative position of the mold-side mark 4 (the mold 2) and the substrate-side mark 5 (the substrate 1) may become deficient.

Hence, as shown in FIGS. 4C and 4D, a mark member 20 made of a material which has optical physical properties different from those of the imprint material 10 and the mold 2 is formed on the mold-side mark 4. As a result, the mold-side mark 4 can be detected even if the mold-side mark 4 (the grooves 4a) is filled with the imprint material 10. FIGS. 4C and 4D show post-liquid contact states. FIG. 4C shows a case in which the mark member 20 has been arranged on the surface of each projection 4b forming the mold-side mark 4, and FIG. 4D shows a case in which the mark member 20 has been arranged on the bottom surface of each groove 4a forming the mold-side mark 4. The mark member 20 has optical physical properties different from those of the imprint material 10 and the mold 2 and is made of a material, for example, Al, Cu, Cr, or the like, which can be comparatively easily used in vapor deposition or the like.

Since forming the mark member 20 on the mold-side mark 4 will allow the mold-side mark 4 to be detected even if the mold-side mark 4 has been filled with the imprint material 10, the relative position of the mold-side mark 4 and the substrate-side mark 5 can be measured. Hence, the positional relationship between the substrate 1 and the mold 2 can be set to a desired state by driving at least one of the substrate stage 11 and the head 3 based on the measurement result of the relative position of the mold-side mark 4 and the substrate-side mark 5.

In general, the mold 2 is cleaned periodically because the imprint material 10 will adhere and become deposited on the mold 2 when the imprint process has been performed for a predetermined number of times. However, cleaning the mold 2 may damage the nark member 20 fomied on the mold-side mark 4 or cause the mark member 20 to peel. In addition, since the mold 2 tends to become easily damaged because it is brought into contact with the imprint material 10 on the substrate for each shot region, the possibility that the mark member 20 will peel increases. Hence, damage and peeling of the mark member 20 become factors in determining the period (lifespan) in which the mold 2 can be used. Since the mold 2 is an expensive member, it is preferable to allow the mold 2 to be used for a longer period when considering the cost of manufacturing a device by the imprint apparatus 100.

Therefore, to suppress damage and peeling of the mark member 20, a protection layer can be arranged on the mark member 20, that is, the protection layer can be arranged to cover the mark member 20. The protection layer is made of a material which will not influence the measurement of the mold-side mark 4, for example, a material (more specifically, SiO₂) which has optical physical properties close to those of the imprint material 10 and the mold 2.

In addition, the dimension of the mold-side mark 4 tends to be larger than the dimension of the pattern of a device region formed on the pattern surface of the mold 2. Hence, it can require time to fill the mold-side mark 4 (the grooves 4a) with the imprint material 10. If the mold-side mark 4 is detected in a state in which the mold-side mark 4 has not been sufficiently filled with the imprint material 10, the measurement light will scatter in each portion (unfilled portion) of the mold-side mark 4 which has not been filled with the imprint material 10. The measurement light that was scattered by the unfilled portion of the mold-side mark 4 will become noise and cause an error in the measurement of the mold-side mark 4. However, if the mold-side mark 4 (the grooves 4a) is buried by the above-described protection layer, it will be possible to set a state in which the mold-side mark 4 has been filled by the protection layer from the beginning without having to fill the mold-side mark 4 with the imprint material 10.

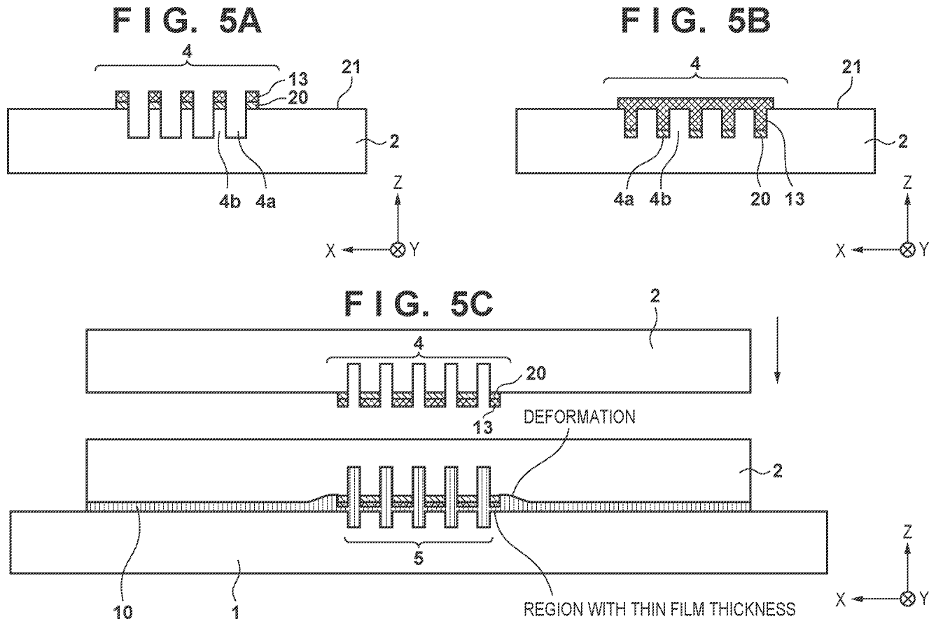

In general, when a protection layer 13 for suppressing damage and peeling of the mark member 20 is arranged on the mold-side mark 4, a portion (mark portion) of the mold-side mark 4 may become higher than the pattern surface 21 (surface) of the mold 2 as shown in FIGS. 5A and 5B. In other words, the mark portion will have a projection structure with respect to the pattern surface 21 of the mold 2. FIG. 5A is a sectional view schematically showing a mark portion structured by arranging the mark member 20 on the surface of each projection 4b of the mold-side mark 4 and further covering each mark member 20 with the protection layer 13. FIG. 5B is a sectional view schematically showing a mark portion structured by arranging the mark member 20 on the bottom surface of each groove 4a of the mold-side mark 4 and further filling each groove 4a with the protection layer 13 to cover each mark member 20 with the protection layer 13. Note that the grooves 4a of the mold-side mark 4 may be filled with a material such as the protection layer 13 in the mark portion shown in FIG. 5A.

When the mold 2 which has the mold-side mark 4 as shown in FIG. 5A or 5B and the imprint material 10 on the substrate are brought into contact with each other, the mark portion which has a projection structure with respect to the pattern surface 21 becomes deformed in the height direction (Z direction) of the mold 2 as shown in FIG. 5C. As a result, the mold 2 will warp, thereby distorting the shot shape.

In addition, as described above, after the mold 2 and the imprint material 10 on the substrate have been brought into contact with each other, the mold 2 and the substrate 1 are aligned by driving at least one of the substrate stage 11 and the head 3 based on the measurement result of the relative position of the mold-side mark 4 and the substrate-side mark 5. At this time, if the mark portion has a projection structure, the film thickness of the portion corresponding to the mark portion of the imprint material 10 on the substrate will become thin or will influence the driving operation by interfering with the projection and groove structure on the substrate.

In accordance with these factors, the thickness of the pattern formed by the imprint material 10 on the substrate by separating the mold 2 from the cured imprint material 10 on the substrate becomes nonuniform. Since etching or the like will be performed by using the partem formed by the imprint material 10 on the substrate as a mask in the next and subsequent processes, the etching operation will be influenced if the thickness of the pattern of the imprint material 10 is nonuniform.

Hence, this embodiment provides the mold 2 and a method of manufacturing the mold 2 which is advantageous in the point of detecting the mold-side mark 4 in a state in which the mold is in contact with the imprint material on the substrate, and in the point of suppressing deformation when the mold is brought into contact with the imprint material even in a case in which the mark member 20 and the protection layer 13 are formed on the mold-side mark 4.

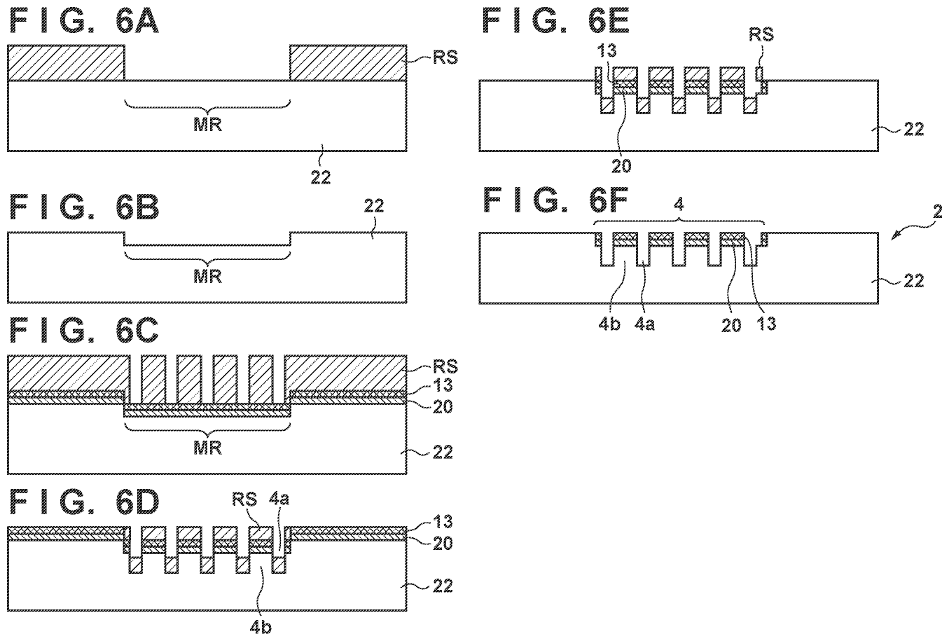

A method of manufacturing the mold 2 according to this embodiment, more specifically, a method of manufacturing the mold 2 which has a structure (FIG. 5A) in which the mark member 20 and the protection layer 13 have been formed on each projection 4b of the mold-side mark 4 will be described with reference to FIGS. 6A to 6F. Note that although the pattern to be transferred onto the substrate 1 is formed on the mold 2, the formation of the mold-side mark 4 will be mainly described here since the pattern formation of the mold is performed in a manner similar to a conventional technique.

First, as shown in FIG. 6A, a region, excluding a mark region MR on which the mold-side mark 4 is to be formed, on the surface of a base member 22 which is to be the pattern surface 21 of the mold 2 is masked with a resist (resin) RS. For example, the region excluding the mark region MR can be masked with the resist RS by applying the resist RS onto the entire surface of the base member 22, exposing (photosensitizing) the resist RS on the mark region MR by an exposure apparatus or the like, and subsequently peeling (removing) the exposed resist RS. In this embodiment, an exposure process and a peeling process are performed so as to open the mark region MR on the surface of the base member 22.

Next, as shown in FIG. 6B, the surface of the base member 22 is processed so that the mark region MR will have a groove structure with respect to the region excluding the mark region MR, more specifically, the pattern region which is to be transferred to the substrate 1. For example, by etching the base member 22 (FIG. 6A) whose region excluding the mark region MR has been masked with the resist RS, the mark region MR which is outside the region masked with the resist RS will be recessed. As a result, the mark region MR can be formed into a groove structure.

Next, as shown in FIG. 6C, the mark member 20 and the protection layer 13 are sequentially formed (arranged) on the surface of the base member 22 in which the mark region MR has been formed to have a groove structure. Furthermore, the resist RS is applied on top of this formation, and a mark pattern corresponding to the mold-side mark is drawn by an electron-beam drawing apparatus or the like. Since the properties of the resist RS on which the mark pattern has been drawn will change, the resist RS can be peeled (removed) by development. In this process, the pattern region (not shown) will also undergo a similar process.

Next, the grooves 4a and the projection 4b forming the mold-side mark 4 are formed by etching the opening region (the mark pattern) of the resist RS and peeling the resist RS. Subsequently, as shown in FIG. 6D, the resist RS is applied again, and an electron-beam drawing apparatus or the like is used to peel the resist RS from each unnecessary region while maintaining the resist RS on each region necessary as the mold-side mark 4.

Next, as shown in FIG. 6E, the mark member 20 and the protection layer 13 on each region that has not been masked with the resist RS is peeled.

Finally, as shown in FIG. 6F, the resist RS is peeled. As a result, the mold 2 which has a structure in which the mark member 20 and the protection layer 13 are arranged on each projection 4b of the mold-side mark 4 is manufactured.

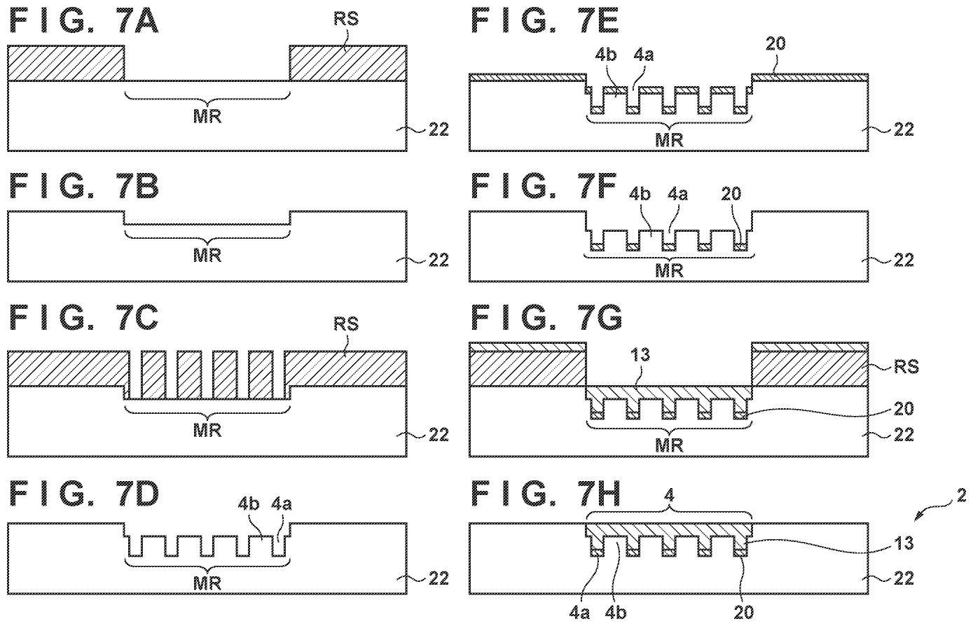

A method of manufacturing the mold 2 according to this embodiment, more specifically, a method of manufacturing the mold 2 which has a structure (FIG. 5B) in which the mark member 20 and the protection layer 13 have been formed on each groov e 4a of the mold-side mark 4 will be described with reference to FIGS. 7A to 7H. Note that although the pattern to be transferred onto the substrate 1 is formed on the mold 2, the formation of the mold-side mark 4 will be mainly described here since the pattern formation of the mold is performed in a manner similar to a conventional technique.

First, as shown in FIG. 7A, a region, excluding the mark region MR on which the mold-side mark 4 is to be formed, on the surface of a base member 22 which is to be the pattern surface 21 of the mold 2 is masked with the resist (resin) RS. The region excluding the mark region MR can be masked with the resist RS by applying the resist RS onto the entire surface of the base member 22, exposing the resist RS on the mark region MR by an exposure apparatus or the like, and subsequently peeling the exposed resist RS in the manner described above. In this embodiment, the exposure process and the peeling process are performed so as to open the mark region MR on the surface of the base member 22.

Next, as shown in FIG. 7B, the surface of the base member 22 is processed so that the mark region MR will have a groove structure with respect to the region excluding the mark region MR, more specifically, the pattern region which is to be transferred to the substrate 1. For example, by etching the base member 22 (FIG. 7A) whose region excluding the mark region MR has been masked with the resist RS, the mark region MR which is outside the region masked with the resist RS will he recessed. As a result, the mark region MR can be formed into a groove structure.

Next, as shown in FIG. 7C, the resist RS is applied to the surface of the base member 22 in which the groove structure has been formed in the mark region MR, and a mark pattern corresponding to the mold-side mark 4 is transferred. In this case, the pattern to be formed in the pattern region can be simultaneously transferred to manage the relative position of the mold-side mark 4 and the pattern to be formed in the pattern region. Hence, an apparatus such as an electron-beam drawing apparatus or the like which can draw a micropattern can be used in this process.

Next, as shown in FIG. 7D, the grooves 4a and the projection 4b forming the mold-side mark 4 are formed by etching the opening region (mark pattern) of the resist RS and peeling the resist RS.

Next, as shown in FIG. 7E, the mark member 20 is formed on the surface of the base member 22 in which the grooves 4a and the projection 4b forming the mold-side mark 4 have been formed. At this time, each groove 4a forming the mold-side mark 4 may be filled sufficiently with the mark member 20.

Next, as shown in FIG. 7F, the mark member 20 formed on the surface layer (on each projection 4b and the region excluding the mark region MR) of die base member 22 is peeled by dry etching or the like so that only the mark member 20 formed on the bottom surface of each groove 4a of the mold-side mark 4 will remain.

Next, as shown in FIG. 7G, the region excluding the mark region MR is masked with the resist RS to form the protection layer 13 on the mark region MR (and the region excluding the mark region MR).

Finally, as shown in FIG. 7H, the resist RS is peeled. As a result, the mold 2 which has a structure in which the mark member 20 and the protection layer 13 have been arranged on each groove 4a of the mold-side mark 4 is manufactured.

In this manner, in this embodiment, the mark region MR on the surface of the base member 22 which is to be the pattern surface 21 of the mold 2 is processed by recessing the surface of the base member 22 so as to form the mark region MR in a position lower than the pattern region (FIGS. 6A and FIG. 6B, and FIGS. 7A and 7B). Subsequently, the mark member 20 and the protection layer 13 are arranged in the mark region MR which has been recessed lower than the pattern region (FIGS. 6C to 6F and FIGS. 7C to 7H). At this time, the mark member 20 and the protection layer 13 are arranged on the mask region MR so that the surface of the pattern to be transferred to the substrate 1 will be at the same height as that of the surface of the mold-side mark 4. As a result, the mold 2 which includes each mold-side mark 4 which is substantially flush with the pattern surface 21 can be manufactured without making the portion of each mold-side mark 4 higher than the pattern surface 21 (front surface) of the mold 2. Using such mold 2 will prevent, even f the mark member 20 and the protection layer 13 have been arranged, the portion of each mold-side mark 4 from becoming deformed in the Z direction when the mold 2 and the imprint material 10 are brought into contact with each other, thereby suppressing warping of the mold 2 and distortion of the shot shape.

Although this embodiment described a case in which the mark member 20 and the protection layer 13 are arranged so that the surface of the pattern to be transferred to the substrate 1 and the surface of each mold-side mark 4 will be at the same height, the present invention is not limited to this. In the point of view of suppressing the deformation of the portion of each mold-side mark 4, it is sufficient as long as a difference between the height of the surface of the mold-side mark 4 and the height of the surface of the pattern to be transferred onto the substrate 1 falls within a predetermined range (to be described later). Hence, the mark member 20 and the protection layer 13 may be arranged so that the difference between the height of the surface of the mold-side mark 4 and the height of the surface of the pattern to be transferred onto the substrate 1 will fall within a predetermined range.

In addition, although the entire groove structure formed in the mark region MR is filled with the protection layer 13 as shown in FIGS. 7G and 7H in this embodiment, only each groove 4a in which the mark member 20 has been arranged may be filled with the protection layer 13. Since the difference between the height of the surface of the mold-side mark 4 and the height of the surface of the pattern to be transferred onto the substrate 1 will fall within a predetermined range in this case as well, it will be possible to suppress the deformation of the portion of each mold-side mark 4 in the Z direction when the mold 2 and the imprint material 10 on the substrate are brought into contact with each other.

Furthermore, although a groove structure is formed in the mark region MR before each groove 4a and each projection 4b forming the mold-side mark 4 are formed and the portion of each mold-side mark 4 and the pattern surface 21 (surface) of the mold 2 are ultimately arranged to be flush with each other in this embodiment, the present invention is not limited to this. For example, after the grooves 4a and the projections 4b forming each mold-side mark 4 have been formed, each projection 4b may be recessed, and the mark member 20 and the protection layer 13 may be sequentially arranged on the surface of each projection 4b that has been recessed. As a processing method for recessing each projection 4b, the following three processing methods can be raised. Note that when the mold 2 is to be manufactured, one processing method among the following three processing methods can be selected by considering how easily the mark member 20 and the protection layer 13 can be processed, the cost, the effort and time of the process, and the like.

The first processing method is polishing. In a semiconductor manufacturing process, CMP (Chemical Mechanical Polishing) is used to flatten a substrate surface after a stacking process. More specifically, CMP is a polishing process that flattens the substrate surface by polishing the substrate surface with a polishing agent called slurry. Such a polishing processing can be applied to the manufacturing process of the mold 2 to recess each projection 4b and to ultimately implement a structure in which the surface of the pattern to be transferred to the substrate 1 will be at the same height as that of the surface of each mold-side mark 4.

The second processing method is etching. More specifically, the processes shown in FIGS. 6A and 6B and in FIGS. 7A and 7B are applied to the mark region MR in which the grooves 4a and the projections 4b have been formed. Although a lithography process and an etching process will need to be added in this case, technical obstacles can be avoided since they are processes which are already present in the overall process.

The third processing is cutting. In recent years, an apparatus that can perform processing to shave off only a protruding portion (micro region) has been developed. For example, an FIB (Focused Ion Beam) apparatus is an apparatus that performs sputtering by focusing, via an electrostatic lens, ions emitted from an ion source onto a set region on a sample and irradiating the set region with the ions. For example, gallium (Ga) can be used as an ion source and processing can be performed from a comparatively heavy atomic weight. For example, by focusing an ion beam on the projection 4b of the mold-side mark 4 and irradiating the projection 4b with the ion beam for a predetermined time, each projection 4b can be shaved off (recessed) to ultimately implement a structure in which the surface of the pattern to be transferred to the substrate 1 and the surface of the mold-side mark 4 are the same height.

By using one of such methods to perform processing after the formation of the mark portion, it will be possible to make the height of the mark portion match the height of the portion outside the mark portion by sufficiently filling the mold with only the mark member 20 without an additional process to the mold in advance or by further adding a protection layer and subsequently performing a removal process.

The mark portion and a portion other than the mark portion are processed to be substantially flush with each other by performing the above-described processes. When an imprint process is performed by using such a mold, a thin resin layer formed by curing the imprint material will be arranged on the pattern surface as described above. It has been found by simulation that various kinds of influence will occur at this time if the ratio of the thicknesses (a step) between the mark portion of the mold 2 and the potion other than the mark portion to the thickness (residual layer thickness) of the imprint material resin layer made becomes greater than ⅕.

For example, if a step larger than 3 nm occurs between an area of the mark portion and an area of the portion other than the mark portion in a case in which the thickness of the imprint material resin layer is 15 nm, warping will occur and the nonuniformity of the resin layer will start to have pronounced influence on the performance.

Therefore, it is preferable to use the methods described in this embodiment to set the thickness (a step) between an area of the mark portion and an area of the portion other than the mark portion to fall within a range of ⅕ of the thickness (residual layer thickness) of the resin layer during the imprint process. In other words, it is preferable to adjust the height by arranging a protection layer or the like so that the difference between the height of the surface of each mark and the height of the surface of the pattern will fall within a predetermined range which is set in accordance with the thickness of the resin layer.

Note that since the influence of a mark pattern is small because each mark pattern is a microscopic design, attention has been paid to the influence from the projection and groove portion of the entire mark portion.

The imprint apparatus 100 uses the mold 2 which has the above-described structure to perform an imprint process of forming an imprint material pattern on a substrate. The imprint process includes a process of curing the imprint material in a state in which the mold 2 and the imprint material on the substrate are in contact with each other and separating the mold 2 from the cured imprint material on the substrate. Since the mold 2, which is advantageous in the point of detecting each mold-side mark 4 in a state in which the mold is in contact with the imprint material and in the point of suppressing deformation when the mold is brought into contact with the imprint material, is used during this time, a pattern corresponding to the pattern of the mold 2 can be formed highly accurately on the substrate.

The pattern of a cured product formed using the imprint apparatus 100 is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

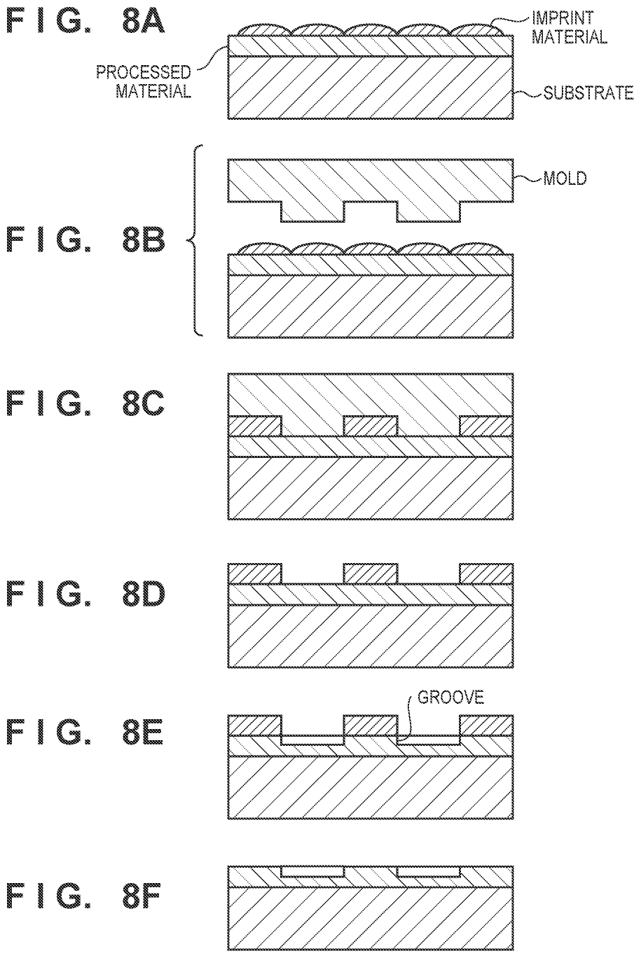

Next, description regarding a detailed method of manufacturing an article is given. As illustrated in FIG. 8A, the substrate such as a silicon wafer with a processed material such as an insulator formed on the surface is prepared. Next, an imprint material is applied to the surface of the processed material by an inkjet method or the like. A state in which the imprint material is applied as a plurality of droplets onto the substrate is shown here.

As shown in FIG. 8B, a side of the mold for imprint with a projection and groove pattern is formed on and caused to face the imprint material on the substrate. As illustrated in FIG. 8C, the substrate to which the imprint material is applied is brought into contact with the mold, and a pressure is applied. The gap between the mold and the processed material is filled with the imprint material. In this state, when the imprint material is irradiated with light serving as curing energy through the mold, the imprint material is cured.

As shown in FIG. 8D, after the imprint material is cured, the mold is released from the substrate. Thus, the pattern of the cured product of the imprint material is formed on the substrate. In the pattern of the cured product, the groove of the mold corresponds to the projection of the cured product, and the projection of the mold corresponds to the groove of the cured product. That is, the projection and groove pattern of the mold 4z is transferred to the imprint material.

As shown in FIG. 8E, when etching is performed using the pattern of the cured product as an etching resistant mask, a portion of the surface of the processed material where the cured product does not exist or remains thin is removed to form a groove. As shown in FIG. 8F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2019-223000 filed on Dec. 10, 2019, which is hereby incorporated by reference herein in its entirety.

What is claimed is:

1. A method of manufacturing a mold that is used to mold an imprint material and includes a pattern surface on which a pattern to be transferred to a substrate and a mark to be used for alignment with respect to the substrate are formed, the method comprising:
performing a first process of processing a surface of a base member so that a mark region where the mark is to be formed on the surface of the base member, which is to be the pattern surface of the mold, will be recessed lower than a pattern region where the pattern is to be formed; and
performing a second process of arranging, on the mark region which has been recessed lower than the pattern region, a mark member made of a material which has an optical physical property different from an optical physical property of the mold and a protection layer configured to cover the mark member so that a difference between a height of a surface of the mark and a height of a surface of the pattern will fall within a predetermined range.

2. The method according to claim 1, wherein in the performing the second process, the mark member and the protection layer are arranged so that the difference will fall within a range of ⅕ of a thickness of an imprint material layer formed on the substrate by molding the imprint material by the mold.

3. The method according to claim 1, wherein in the performing the second process, the mark member and the protection layer are arranged in the mark region which has been recessed lower than the pattern region so that the surface of the pattern and the surface of the mark will be at the same height.

4. The method according to claim 1, wherein in the performing the first process, the surface of the base member is processed so that the mark region will have a groove structure with respect to the pattern region.

5. The method according to claim 4, further comprising:
performing a third process of forming a groove and a projection which form the groove structure of the mark,
wherein in the performing the second process, the mark member and the protection layer are arranged on one of the groove and the projection which form the groove structure.

6. The method according to claim 5, wherein the performing the second process includes
arranging the mark member on a surface of the projection, and
arranging the protection layer on the mark member arranged on the surface of the projection.

7. The method according to claim 5, wherein the performing the second process includes
arranging the mark member on a bottom surface of the groove, and
filling the groove, in which the mark member has been arranged, with the protection layer.

8. The method according to claim 7, wherein in the filling the groove, the entire groove structure is filled with the protection layer.

9. The method according to claim 1, farther comprising:
performing a third process of forming a groove and a projection which form the groove structure of the mark,
wherein in the performing the first process, the projection formed in the performing the third process is recessed, and
the performing the second process includes
arranging the mark member on a surface of the projection recessed in the performing the first process, and
arranging the protection layer on the mark member arranged on the surface of the projection.

10. The method according to claim 1, wherein the mark member is made of a material which has an optical physical property different from an optical physical property of the imprint material.

11. A mold that is used to mold an imprint material and includes a pattern surface on which a pattern to be transferred to a substrate and a mark to be used for alignment with respect to the substrate are formed, comprising:
a base member which includes a surface to be the pattern surface of the mold;
a mark member made of a material which has an optical physical property different from an optical physical property of the mold; and
a protection layer configured to cover the mark member,
wherein the base member includes a portion in which a mark region where the mark is to be formed has been recessed lower than a pattern region where the pattern is to be formed, and
the mark member and the protection layer are arranged in the portion so that a difference between a height of a surface of the mark and a height of a surface of the pattern will fall within a predetermined range.

12. An imprint method that uses a mold to form a patient on an imprint material on a substrate, the method comprising:
manufacturing a mold that is used to mold an imprint material and includes a pattern surface on which a pattern to be transferred to a substrate and a mark to be used for alignment with respect to the substrate are formed; and
curing the imprint material in a state in which the mold manufactured in the manufacturing is in contact with the imprint material on the substrate and separating the mold from the cured imprint material on the substrate,
wherein the manufacturing the mold includes
performing a first process of processing a surface of a base member so that a mark region where the mark is to be formed on the surface of the base member, which is to be the pattern surface of the mold, will be recessed lower than a pattern region where the pattern is to be formed, and
performing a second process of arranging, on the mark region which has been recessed lower than the pattern region, a mark member made of a material which has an optical physical property different from an optical physical property of the mold and a protection layer configured to cover the mark member so that a difference between a height of a surface of the mark and a height of a surface of the pattern will fall within a predetermined range.

13. An imprint apparatus that uses a mold to form a pattern on an imprint material on a substrate, comprising:
a head configured to hold and move the mold,
wherein the mold includes a mold defined in claim 11.

14. An article manufacturing method comprising:
forming a pattern on a substrate using an imprint method defined in claim 12;
processing the substrate on which the pattern is formed in the forming; and
manufacturing an article from the processed substrate.
